(19) United States
(12) Patent Application Publication
(10) Pub. No.: US 2007/0253040 A1
(43) Pub. Date: Nov. 1, 2007

(54) Color scanning to enhance bitonal image

(75) Inventors: Yongchun Lee, Rochester, NY (US); George A. Hadgis, Spencerport, NY (US); Mark C. Rzadca, Fairport, NY (US)

Correspondence Address: Mark G. Bocchetti;Patent Legal Staff, Eastman Kodak Company, 343 State Street, Rochester, NY, 14650-2201, US

(73) Assignee: Eastman Kodak Company

(21) Appl. No.: 11/414,747

(22) Filed: Apr. 28, 2006

(51) Int. Cl. G03F 3/08

(52) U.S. Cl. 358/518

(57) ABSTRACT

A method for obtaining bitonal image data from a document obtains scanned color image data from at least two color channels and identifies, in the scanned color image data, at least one region of interest (R1) containing foreground content and background content. At least one threshold data value is obtained according to an image attribute that differs between the foreground content and the background content within the region of interest (R1). The scanned color image data of the document is converted to bitonal image data according to the at least one threshold data value obtained from the region of interest (R1).

### FIELD OF THE INVENTION

This invention generally relates to image thresholding and separation of foreground from background images and more particularly relates to a method for obtaining a high quality bitonal image from a document that has a significant amount of background color content.

### BACKGROUND OF THE INVENTION

In a production scanning environment, the digital output of a scanned paper document is often represented and stored in binary (black and white) form because of its greater efficiency in storage and transmission, particularly for textual images. Binary form is also well suited to text scanning and optical character recognition (OCR).

Typically, a scanner is used for scanning a document in order to obtain, from a charge coupled device (CCD) sensor, digital grey scale signals at 8 bits per pixel. Conversion of this 8-bit per pixel grey scale data to 1-bit per pixel binary data then requires some type of image thresholding process. Because image thresholding is an image data reduction process, it often results in unwanted image artifacts or some loss or degradation of image information loss. Errors in image thresholding can cause problems such as speckle noise in the document background or loss of low contrast characters.

There have been a number of attempts to improve image thresholding and obtain a binary image of improved quality. For example, commonly-assigned U.S. Pat. No. 4,868,670 (Morton et al.) discloses tracking a background value in an image, with a threshold value being a sum of a tracked background value, a noise value, and a feedback signal. Whenever an edge or other transition occurs in the image, the feedback signal is momentarily varied in a pre-defined pattern to momentarily modify the threshold value so that an output filtered thresholded pixel value has a reduced noise content. However, background tracking prevents significant difficulties, particularly where objects of interest are at relatively low contrast. A different approach is the adaptive thresholding described in U.S. Pat. No. 4,468,704 (Stoffel et al.) Here, thresholding is implemented by using an image offset potential, which is obtained on a pixel-by-pixel basis as a function of white peak and black valley potentials in the image. This offset potential is used in conjunction with nearest neighbor pixels to provide an updated threshold value that is adaptive, varying pixel-by-pixel. The peak and valley potentials are generated, for each image pixel, by comparing the image potential of that pixel with predetermined minimum white peak and maximum black valley potentials. Unfortunately, this technique also appears to exhibit difficulties in extracting low contrast objects in a thresholded image.

Commonly-assigned U.S. Pat. No. 5,583,659 (Lee et al.), incorporated herein in its entirety, discloses significant improvements to adaptive thresholding, such as is done on a pixel-by-pixel basis in the general scheme outlined in the '704 Stoffel et al. patent listed earlier. In the method described, localized intensity gradient data is first computed for each scanned greyscale pixel and can be used to determine whether or not the pixel is in the vicinity of an edge transition. Subsequent processing is then performed to further classify the pixel as part of an edge or flat field, object or background. The processed output image is enhanced in this way to provide improved thresholding. Significantly, two variable user inputs are used as thresholds to fine-tune the image data processing. When the best possible values for these variables are obtained, adaptive thresholding provides an image that can be accurately converted to bitonal data.

Extracting text and images of interest from a complex color background can be particularly difficult and the proposed conventional solutions achieve only limited success. For example:
U.S. Pat. No. 6,023,526 (Kondo et al.) describes extracting text data from a color background using direct conversion from a color to a bitonal image based on color filtering or thresholding methods using prior knowledge of text color. While this type of method can be suitable for scanning many types of postal documents and other types of documents having text of a predictable color against a flat field background of another color, such an approach is poorly suited to documents having variable background color content and responds poorly to documents having variable background color content.
U.S. Pat. No. 6,748,111 (Stolin et al.) uses a tiling method to help separate the background color content of a document over local areas. This method applies image partitioning and color clustering in 3-D color space and relies heavily on a number of assumptions known beforehand about document format and the spatial position of text fields. Methods such as that described in the Stolin et al. '111 disclosure do not perform well for isolating text from a complex color background.
U.S. Pat. No. 6,704,449 (Ratner) describes an iterative approach for obtaining color image data for a document that is a standard graphics file format. The Ratner '449 method uses image binarization from each of the composite color channels and then applies OCR processing for confirmation of successful text extraction. This type of method makes some global assumptions about background content that might work for displayed images such as those downloaded from web pages, but would have limited usefulness for scanned checks and similar paper documents that may have complex color backgrounds.
U.S. Pat. No. 6,701,008 (Suino) describes scanning a document and obtaining image data in separate red, green, and blue (RGB) color planes, then using image algorithms to detect linked pixels having the same values in all three color planes in order to detect text areas. Data from the three color planes can then be merged to provide text from the scanned document. However, similar methods have proved disappointing for limiting noise and maximizing image contrast in a bitonal output. This type of method may have some limited success where the text strings or other image content of interest are against a flat background, but is not well suited for documents having text against a complex color background.
U.S. Patent Application No. 2004/0096102 (Handley) describes a method using clustering in 3-D color space to identify the text or image content of interest by color analysis. However, such methods are prone to noise where a document background has more complex color content.

While some of the methods described in these disclosures may be usable for limited types of simple multicolor documents, these methods are not well suited to documents having complex color content. Instead, some additional type of post-processing is typically called for, such as algorithms that connect neighboring pixels to identify likely text characters or OCR techniques for obtaining text character information from noisy greyscale data.

Although advances such as adaptive approaches have been made, and even though it has become practical to scan three-color RGB data from a document, the problem of obtaining accurate thresholding continues to pose a challenge. This difficulty can be particularly acute when it is necessary to scan and obtain text information from documents that have significant background color content.

Recent commercial banking legislation, known to those in banking as personal check 20, has caused heightened interest in the need for more accurate thresholding and conversion of images to binary data. With this legislation, electronically scanned image data from a check can be allowed the same legal status as the original signed paper check document. Scanned check data is used to form an image replacement document (IRD) that serves as a substitute check. Once this electronic image of the check is obtained, the original paper check can then be destroyed. The touted benefits of this development for the banking institution include cost reduction and faster transaction speeds. In the conversion from a paper check to a digital image, the check 21 legislation requires accurate transformation of the data into bitonal or binary form for reasons including reduced image storage requirements and improved legibility.

Even with advances in image scanning and analysis, complex background color content still presents a hurdle to taking advantage of the benefits of check 20 and of other capabilities made possible using an electronically scanned image. For example, while there is at least some standardization of dimensions and of the locations of various information fields on bank checks, there can be considerably different background content from one check to another. So-called “personalized” or custom checks from various check printers can include a variable range of color image content, so that even checks used within the same account can have different backgrounds. To complicate the problem further, there is no requirement that data recorded on the check be written in any particular pen color, which could simplify text extraction for some documents. Moreover, the information regions of interest can be varied from one check to the next. As a result, it can still be difficult to provide a fully automated binary scan of each check where the information of interest is reliably legible. A large percentage of images for scanned checks currently contain excessive background residual content and noise that not only reduce data legibility, but can also significantly increase image file size. File size inefficiencies, in turn, exact cost for added transmission time, storage space, and overall processing overhead, particularly considering the huge number of checks being scanned each day.

Clearly, there is a need for an improved scanning system and process that is capable of producing a clear, readable binary image of text or other image content without the need for a visual image quality inspection and subsequent adjustment of variables and reprocessing. Ideally, an improved system and process would be sufficiently compatible with currently available scanning components to allow the use of the system on scanner equipment that is presently in use, and to minimize the need for the design and manufacture of new components.

### SUMMARY OF THE INVENTION

It is an object of the present invention to provide a method for obtaining bitonal image data from a document comprising:
(a) obtaining scanned color image data from at least two color channels;
(b) identifying, in the scanned color image data, at least one region of interest containing foreground content and background content;
(c) obtaining at least one threshold data value according to an image attribute that differs between the foreground content and the background content within the region of interest; and
(d) converting the scanned color image data of the document to bitonal image data according to the at least one threshold data value obtained from the region of interest.

From another aspect, the present invention provides a method for obtaining a bitonal image from a document comprising:
(a) obtaining scanned color image data from at least two color channels;
(b) identifying, in the scanned color image data, at least one region of interest containing foreground content;
(c) generating a high contrast object grey scale image according to at least one attribute of the foreground content in the at least one region of interest;
(d) generating at least one threshold value for the at least one region of interest according to averaged greyscale values for edge pixels in the foreground content data; and
(e) generating the bitonal image for at least a portion of the high contrast object grey scale image according to the at least one threshold value for the at least one region of interest.

It is a feature of the present invention that it provides threshold values used to obtain a bitonal image based on scanned data from two or more color channels. The scanned color data is used to provide a high contrast object grey scale image that is processed using adaptive thresholding.

It is an advantage of the present invention that it provides a method for obtaining a bitonal image from a scanned document that can provide improved quality over images obtained using conventional methods.

It is a further advantage of the present invention that it provides a method for automating the selection of intensity and gradient thresholds for adaptive thresholding, eliminating the need for operator guesswork to provide these values.

These and other objects, features, and advantages of the present invention will become apparent to those skilled in the art upon a reading of the following detailed description when taken in conjunction with the drawings wherein there is shown and described an illustrative embodiment of the invention.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a logic flow diagram for the method of the present invention;

FIG. 2A is a plan view showing an example for a scanned document having horizontal lines;

FIG. 2B is a plan view showing regions of interest for a scanned document having horizontal lines as in FIG. 2A;

FIG. 3 is a logic flow diagram for generating a high contrast object grey scale image in one embodiment;

FIG. 4 shows a set of logic conditions used for determining the best color channel or channels to use for obtaining a high contrast object grey scale image;

FIG. 5 shows a decision tree for obtaining a high contrast object grey scale image;

FIG. 6 is a plan view showing a single text letter as foreground content in a region of interest in one embodiment;

FIG. 7A is an example of a high contrast object grey scale image for a region of interest;

FIG. 7B shows the region of interest with a number of edge points identified;

FIG. 8 is a logic flow diagram showing steps for obtaining threshold values for adaptive threshold processing;

FIG. 9 is an example of a histogram obtained for the region of interest shown in FIG. 7;

FIG. 10 is an example averaged gradient curve obtained for the region of interest shown in FIG. 7;

FIG. 11A is an example of a document scanned in red, green, and blue color channels;

FIG. 11B is an example of a high contrast object grey scale image for the document of FIG. 11A; and

FIG. 11C is an example of a bitonal image obtained from the document of FIG. 11A using the method of the present invention.

### DETAILED DESCRIPTION OF THE INVENTION

The present description is directed in particular to elements forming part of, or cooperating more directly with, apparatus in accordance with the invention. It is to be understood that elements not specifically shown or described may take various forms well known to those skilled in the art.

Using the method of the present invention, a color scan of a document is obtained and values obtained from the scanned image data are used to generate an enhanced bitonal image with reduced noise content. The color scan data is first used for identifying objects or regions of interest on the document and the most likely color of text or other image content within each region. Within each region of interest, color content of the foreground object of interest and of the background is then detected. Color scan data that shows the intensity or density for a color channel is then analyzed and used to generate a high contrast object grey scale (HCOGS) image. Edge detection logic then detects features having the largest gradient in the region of interest, so that accurate gradient thresholds and intensity thresholds can be generated for control of adaptive thresholding. The high contrast object grey scale image is converted to a bitonal image using adaptive thresholding, employing the generated gradient and intensity thresholds.

The method of the present invention works in conjunction with the multi-windowing adaptive thresholding methods disclosed in the '659 Lee et al. patent noted earlier in the background section. The '659 Lee et al. patent disclosure is incorporated herein in their entirety. In terms of data flow, the methods of the present invention are applied further “upstream” in image processing. The resulting enhanced image and processing variables data that are generated using the method of the present invention can be effectively used as input to the adaptive thresholding procedure noted in the '659 Lee et al. disclosure, thereby providing optimized input and tuned variables for successful execution of adaptive thresholding.

The method of the present invention has the goal of obtaining the best possible separation between foreground content of a document and its background content. The type of foreground content varies depending on the document. For example, with a personal check, foreground content includes text entered by the payor, which may require further processing such as OCR scanning for example. Other types of documents may include printed text foreground content or other image content. Background content may have one or more colors and may include significant amounts of graphic content. Unlike the background, the foreground content is generally of a single color.

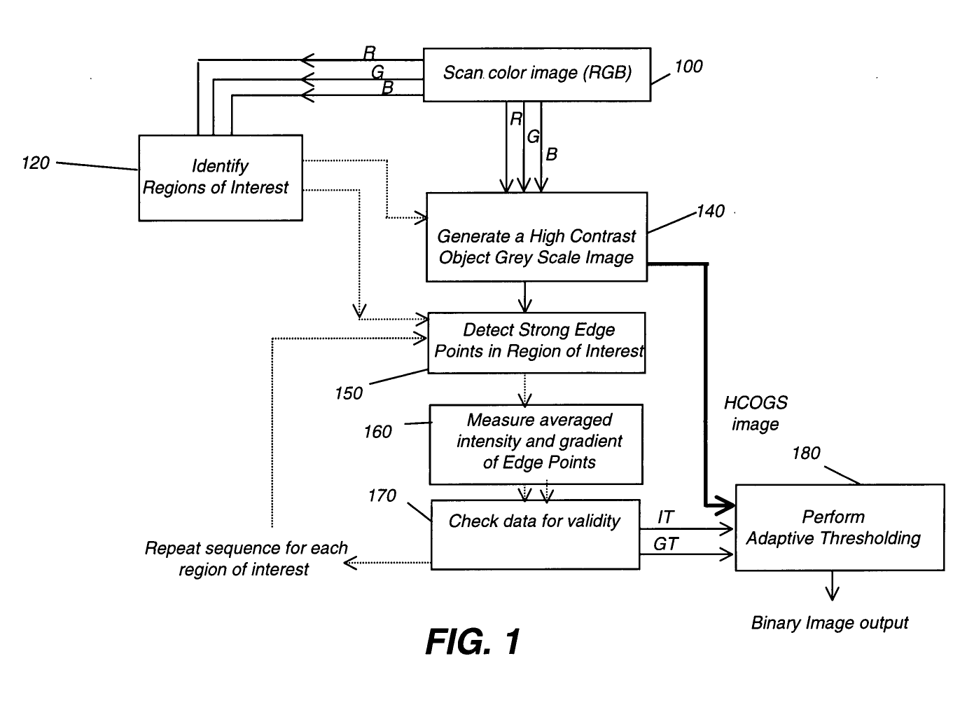

Referring to FIG. 1, there is shown the basic processing sequence for obtaining a bitonal image using the method of the present invention. In an initial scanning step 100, a multicolor scan, such as an RGB color scan, is first obtained from the document. Scanning step 100 generates scanned color image data that is then analyzed and used in subsequent steps for generating a high contrast object grey scale (HCOGS) image and for generating an intensity threshold IT value and a gradient threshold GT value that help to optimize an adaptive thresholding method for extracting the foreground text or image content that is of interest.

An important preparatory step for using the multicolor scan data efficiently is to identify one or more regions of interest on the document. A region of interest can be understood to be an area of the document that contains the foreground text or image content that is of interest and may contain some amount of background content that is not wanted. A region of interest could cover the entire scanned area; however, in most cases, such as with personal checks, there are merely one or more discrete regions of interest located on the document. Typically, regions of interest are rectangular.

An identify regions of interest step 120 is used to perform this function. There are a number of methods for selecting or detecting a region of interest. The method that is most useful in an individual case can depend on the type of document itself. For example, for scanned personal checks or other bank transaction documents, the size of the document and relative locations of its region(s) of interest such as for check amount, payee, and date, for example, are typically well-defined. In such a case, no sophisticated methods would be necessary for identifying a region of interest as part of step 120; it would simply be necessary to determine some base origin point in the scanned data and to measure a suitable relative distance from that origin to locate each region of interest. As one alternate method for identifying regions of interest 120, dimensional coordinate data value entered on a keyboard, or provided using some other user command mechanism such as using a mouse, keypad, or touchscreen, could be employed. Other methods for automatically finding the region of interest could include detecting the edges of horizontal lines using edge detection software. A 1-D Sobel edge detector could be used for this purpose, for example. Edge detection might also be used to help minimize skew effects from the scanned data. When scanning personal checks, for example, there are a small number of reference lines that can be detected in this manner. By performing edge detection over a small range of angles about the vertical, image processing algorithms can determine and compensate for a slight amount of skew in the scanned data.

Among the various techniques that have been proposed for identifying the region of interest containing text against a complex background are those described in the research paper entitled “Locating Text in Complex Color Images” by Yu Zhong, Kalle Karu, and Anil K. Jain in Pattern Recognition, Vol. 28, No. 10, 1995, pp. 1523-1535. Approaches described by these authors include connected component analysis, used for detection of horizontal text characters, where these characters have a color that is sufficiently distinct from the background content. Other approaches include spatial variance analysis, detecting the sharp transitions that indicate a row of horizontal text characters. Authors Zhong, Karu, and Jain also propose a hybrid algorithm that incorporates strengths of both connected component and spatial variance methods. As noted by these authors, however, the methods they employ require empirically tuned parameters and achieve only limited success where the text and background color content are too similar or where text characters are connected to each other, such as in handwritten or cursive text.

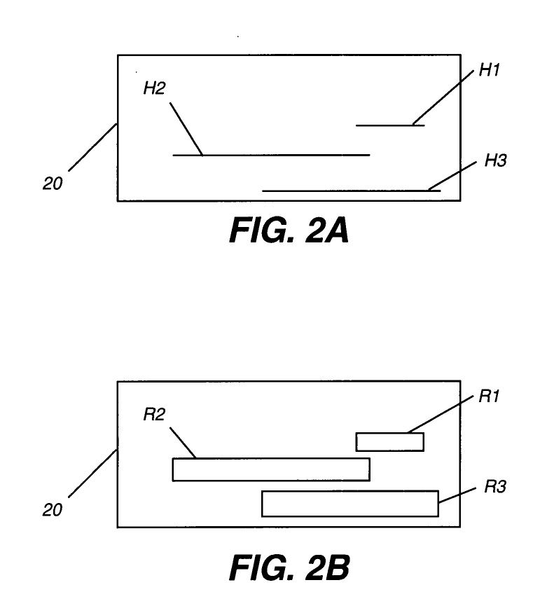

In many cases, documents of a certain class have one or more reference markings that help to locate foreground text or other content of interest. In one embodiment, as shown in FIG. 2A, horizontal lines H1, H2, and H3 serve as reference markings. Edge detection is performed in order to locate horizontal lines H1, H2, and H3 on a personal check 20. This is accomplished by processing the grey scale data obtained from color scan data using a 1-D Sobel edge detection algorithm. The algorithm checks through the scanned data for peak intensity (or black pixel density) values, working through the data in a successive series of vertical lines. Peak values having highest intensity occur at the coordinates of horizontal lines H1, H2, and H3. Once these lines are located, the corresponding regions of interest R1, R2, and R3 can be located on personal check 20, as shown in FIG. 2B. For the simple document in this example, the region of interest can be located simply by constructing a rectangular area positioned at a suitable location relative to the corresponding horizontal line H1, H2, or H3.

Within each identified region of interest, color content of the foreground text or other foreground image content and color content of the background can then be detected as part of identify regions of interest step 120. This can be determined in a number of ways. In one embodiment, the three RGB channels are each checked to determine which channel has the largest contrast difference for the object(s) of interest within the region of interest. Image data from this channel is then used to locate the desired text or foreground image content, based on the observation that the desired image content is darker than the surrounding background. Histogram analysis can be used as a part of this process or as validation to isolate the desired foreground text or image content as being no more than about 20% of the highest density image within the limited region of interest.

Once the set of pixels containing foreground image content have been identified, the data value in each color channel (typically RGB) for each of these pixels is used to determine color of the foreground image or text. This foreground content color is typically computed as the averaged red, green, and blue values of pixels in this set. The background color is then computed as the averaged RGB values of pixels outside the foreground image pixel set. Alternately, a grey scale image could be generated from the scanned color image data and processed to identify one or more regions of interest.

Using the processing steps just described, identify regions of interest step 120 has identified one or more regions of interest on the document and, within each region, the color composition of the foreground text or other image and of the predominant portion of the background in the region of interest. These important image attributes are used for generating the HCOGS image and GT and IT thresholds for each region in the processing steps that follow. It is important to emphasize that each region of interest on a document can be handled individually, allowing the generation of local GT and IT threshold values for each region of interest. This capability may or may not be important in any specific application, but does allow the flexibility to provide bitonal images for documents where background content is highly complex or even where foreground text or image content in different regions of the same document may be in different colors.

Referring again to FIG. 1, with foreground image color and background color determined for each region of interest, a high contrast object grey scale image generation step 140 is executed. As shown in FIG. 1, high contrast object grey scale image generation step 140 uses one or more image attributes from the color detection results of step 120 and the RGB or other multi-channel scan data values obtained in step 100 as inputs. The output is a grey scale image that is formed using one or more of the color planes or color channels in combination. For example, the detected foreground content color in regions of interest on the document could have the most pronounced object contrast in a single color plane. In such a case, the high contrast object grey scale (HCOGS) image can be generated from only one of the color channels, such as Red, Green, or Blue (RGB). Contrast, as one image attribute, can be used, where the contrast between detected foreground and background colors is assessed to determine which of the color channels provide the highest degree of difference, here, optimum object contrast, singly or in combination with another color channel. In some cases, a combination of two color channels could be used. For example, for a predominantly Blue foreground object, averaging of the Red and Green values can be appropriate, so that each grey scale value is formed as a pixel using:

$$\frac{R + G}{2}$$

As yet another alternative, the HCOGS image can be generated from all three of the color channels. For example, for a substantially neutral foreground object, an averaging of the Red, Green, and Blue values may be used, so that each grey scale value is formed as a pixel using:

$$\frac{R + G + B}{3}$$

Still other alternatives for arriving at a grey scale value include more complex combinations using weighted values, such that each color plane value has a scalar multiplier or where division is by other than an integer, as in the following example:

$$\frac{0.9 R + 1.2 G + 1.0 B}{3.04}$$

The exemplary sequence that follows illustrates how the high contrast object grey scale image can be obtained for personal check 20 of FIGS. 2A and 2B, scanned as RGB color data in one embodiment. For region of interest R2 on personal check 20, the following data representation is used:
Color of text or other foreground image in R2: (R₂ₜG₂ₜB₂ₜ)
Color of background in R2: (R_{b}G_{b}B_{b})

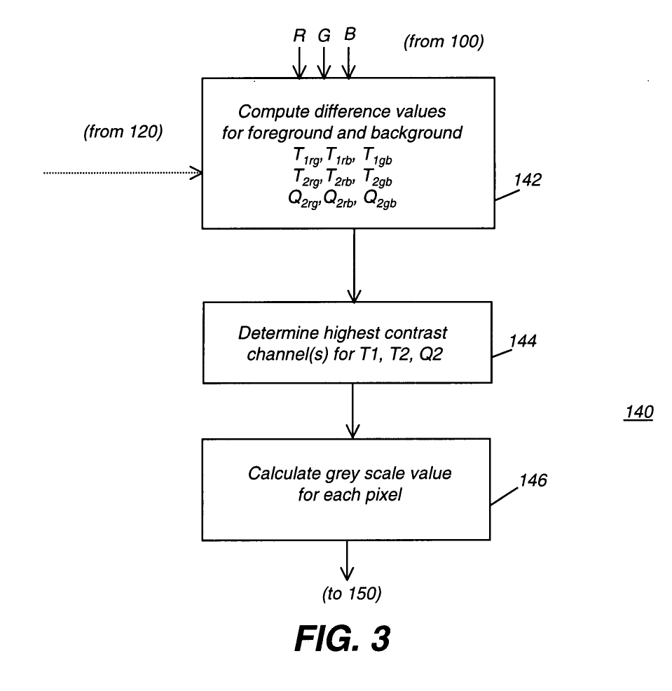

As is shown for the expanded high contrast object grey scale image generation step 140 in FIG. 3, a set of values is computed for the foreground color in each region of interest in a computation step 142. For region R2, the following computations are made, where T represents the difference between foreground color values for specific color channels and subscripts represent the corresponding color channels:
T_{2rg}=|R₂ₜ−G₂ₜ|
T_{2rb}=|R₂ₜ−B₂ₜ|
T_{2gb}=|G₂ₜ−B₂ₜ|

For the background in region R2, the small letter b in subscripts indicates the measured background value in the data and Q represents the difference in computed background color value, computed using the different color channels, as follows:
Q_{2rg}=|R_{2b}−G_{2b}|
Q_{2rb}=|R_{2b}−B_{2b}|
Q_{2gb}=|G_{2b}−B_{2b}|

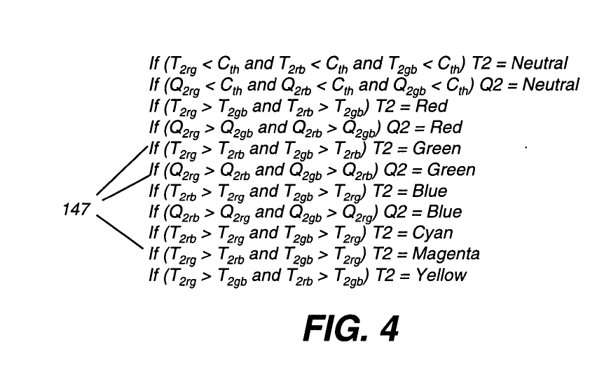

Still referring to FIG. 3, a contrast determination step 144 follows. FIG. 4 shows logic conditions 147 used to determine the color channel or channels that exhibit the highest contrast levels for foreground (T) and background (Q) content. Value Cₜₕ indicates a threshold value, determined empirically. In some cases, a single color channel is best used for foreground or background content. For example, where background value Q_{2rg} exceeds value Q_{2gb} and value Q_{2rb} exceeds Q_{2gb}, then background value Q2 is Red, as shown in the fourth line of FIG. 4.

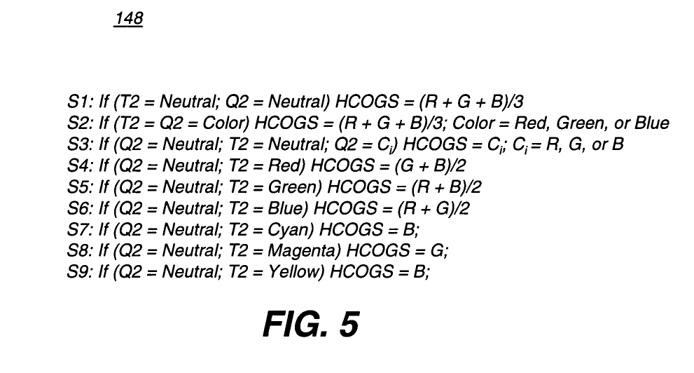

FIG. 5 then shows a decision tree 148 used to complete a calculation step 146 in FIG. 3. Substeps S1 through S9 are shown for each of various possible color determinations made using logic conditions 147 of FIG. 4. HCOGS stands for the value of the High Contrast Object Grey Scale computation. Cᵢ stands for the high intensity color channel. As has been noted earlier, this sequence indicates one example set of logic flow steps that operate in one embodiment of the present invention. Other arrangements can also be used in other embodiments, with a similar type of sequencing and with outcomes adjusted differently, all within the scope of the present invention.

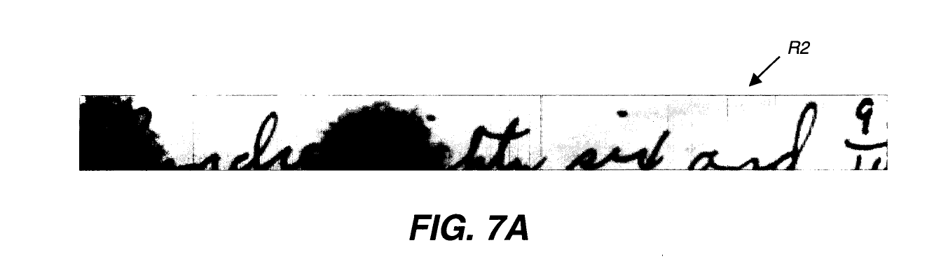

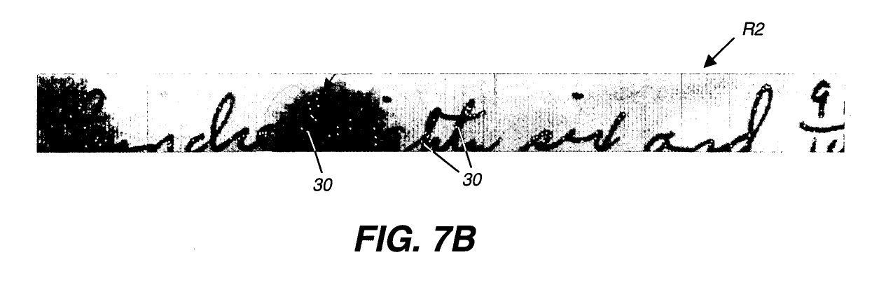

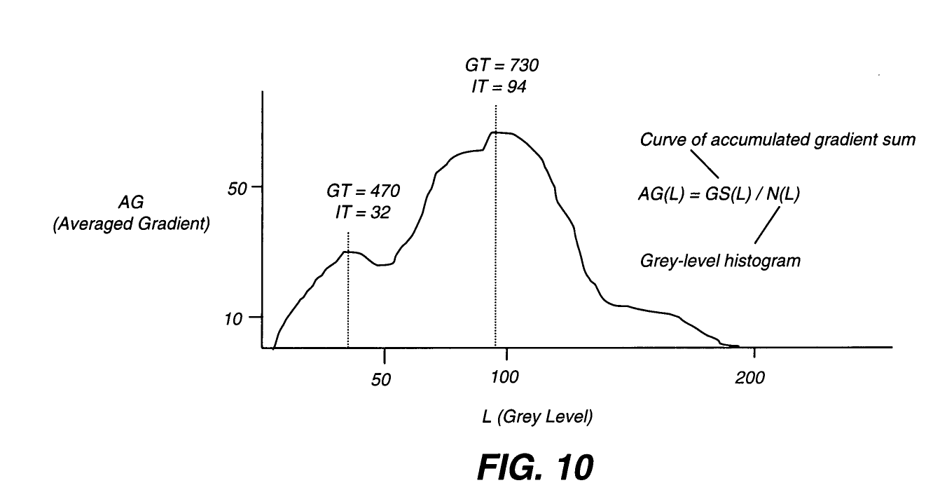

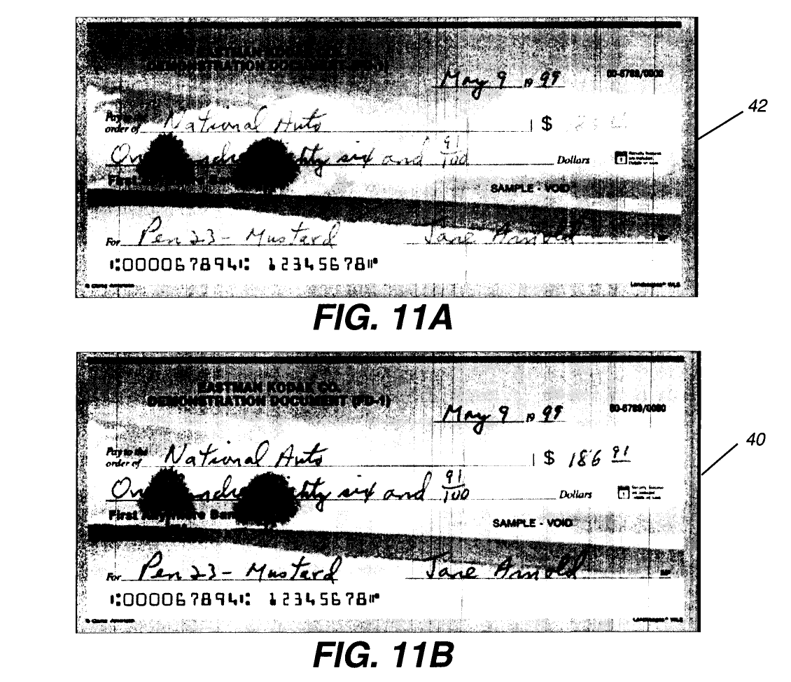

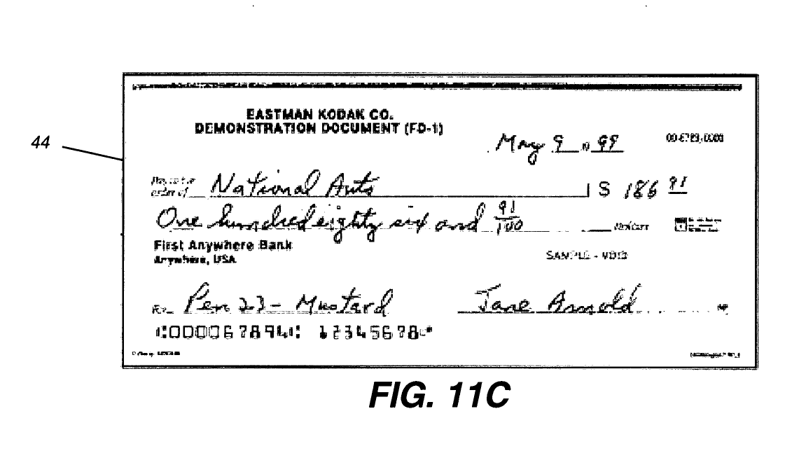

By way of example, FIG. 11A shows a resulting color image 42 (shown as a grey scale image in this application) initially obtained from an RGB color scan. FIG. 11B shows an enhanced HCOGS image 40 obtained. FIG. 11C shows the final bitonal or binary image 44, obtained using adaptive thresholding with threshold values GT=470 and IT=32, as indicated in FIG. 10. For this example, approximate RGB intensity values for foreground content obtained from region of interest R2, a portion of which is shown in FIG. 7, were (R=200, G=80, B=40). Background content had RGB values of (R=230, G=220, B=210). As shown in FIG. 4, lines 2 and 3, the background value is computed to be Neutral, foreground text content is considered Red. Following step S4 in FIG. 5, the optimum HCOGS image is obtained using:

$$\frac{G + B}{2}$$

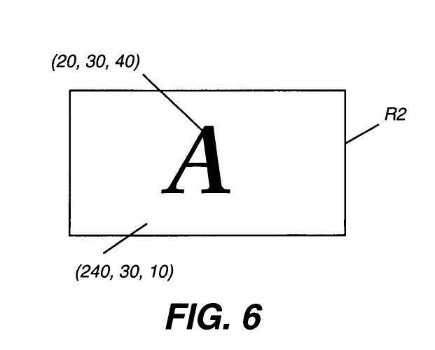

In this way, at the conclusion of high contrast object grey scale image generation step 140 (FIG. 1), a high contrast object grey scale image is obtained from the scanned RGB color data. The sequence of steps that follow obtain and validate other parameters that will be used in an implementation of an adaptive thresholding step 180 for obtaining a bitonal image output. An example of this step is shown for a single foreground text letter in FIG. 6. Here, in region R2, the letter A has RGB channel values (20, 30, 40) indicating a neutral value for foreground text content. The background content within region R2 is reddish, with RGB channel values of (200, 30, 10). Following the logic condition 147 of the first line in FIG. 4, text letter A is best identified as having a neutral coloring. Here, the highest contrast between foreground text content and the background is given in the Red channel. If similar text in another region of interest R2 also shows neutral, HCOGS is then determined using substep S3 of decision tree 148 of FIG. 5. Following this logic, the Red color channel is equal to Cᵢ. and provides the best high contrast object grey scale image.

The next sequence of steps, shown in FIG. 1, provides gradient threshold (GT) and intensity threshold (IT) values used for adaptive thresholding. As noted earlier, it is an advantage of the method of the present invention that these threshold values can be generated separately for each region of interest on a document. In an edge detection step 150, edge detection logic is applied to detect features having the largest gradient in the region of interest. To do this, gradient distribution data is generated for each grey level in the region and a grey level histogram is maintained. An averaged gradient distribution value for each grey level is then obtained by dividing the accumulated gradient values by the number of pixels at that grey level. Peak values obtained from this gradient distribution calculation indicate candidate strong edge points for the image content of interest.

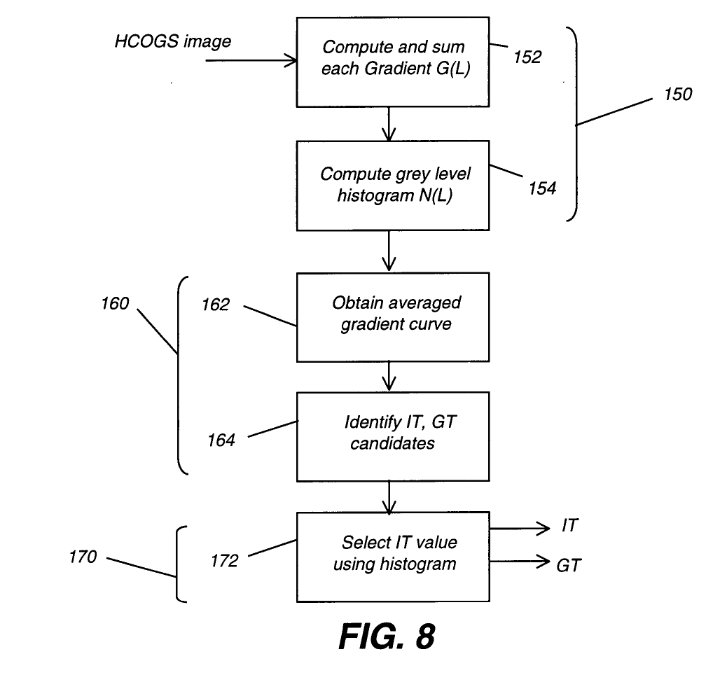

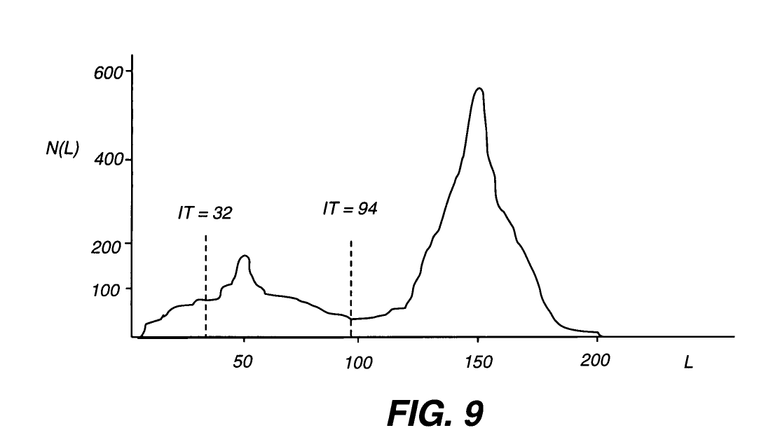

FIG. 7A shows an example region R2 as a field on a personal check 20. FIG. 7B shows this region R2 with identified edge points 30. Given this example, FIG. 8 shows a sequence of steps that can be used to detect strong edge points in this region of interest as part of edge detection step 150, to obtain averaged intensity and gradient of the edge points in a measurement step 160 and to validate the data in a validity check step 170. A gradient computation step 152 obtains the gradient value at each pixel in region R2. For this step, a 3×3 Sobel operator or other gradient measurement mechanism can be used to obtain a gradient value at each pixel location. As each gradient value is obtained, an accumulative sum is maintained for each grey scale value. As this process is carried out, a histogram maintenance step 154 is also executed. In this step, a histogram is maintained, as shown in FIG. 9. A familiar statistical tool, the histogram curve graphically shows the count obtained for each grey scale value L. The individual value for a particular grey scale value L is represented as N(L).

Thus, for example, each time a pixel having a grey scale value (L) of 112 is encountered, the gradient value obtained at that pixel is added to all previous gradient values for grey scale value 112. In this way, an accumulated sum GS(L) is obtained for each grey scale value L. For example, if the histogram shows that there are 67 pixels having a grey scale value of 112, the accumulated sum GS(112) is the accumulated total of all of the 67 gradient values obtained for these pixels.

In order to use these summed values, an averaged gradient AG(L) is computed as part of an averaged gradient computation step 162. To obtain an averaged gradient for each grey scale value L, the following straightforward division is used:
AG(L)=GS(L)/N(L)
Thus, continuing with the example given earlier, for the 67 pixels having a grey scale value of 112, the corresponding averaged gradient AG(112) is computed as:
AG(112)=GS(112)/67

This computation is executed for each grey scale value L. The result can be represented as is shown in FIG. 10. Here, the computed gradient values AG(L) are represented as ordinate values (on a times 10 scale in FIG. 10) with the individual grey levels L along the abscissa. As the AG(L) curve in FIG. 10 shows, peak values in this curve, identified in a candidate identification step 164 (FIG. 8) indicate strong edge points that serve as the candidate edge points for further analysis. These values are labeled as gradient threshold GT and intensity threshold IT values. Small gradient values AG(L) indicate flat areas in the background.

Still referring to FIG. 8, it now remains to sort through the candidate GT and IT values as part of a selection step 172 in order to determine the most likely GT and IT values for use in adaptive thresholding for extracting text or other foreground content within the region of interest. To perform this selection, the histogram of FIG. 9 is used, along with empirically determined rules of thumb for eliminating less likely candidate GT and IT values. For this purpose, a text area percentage is employed. Based on empirical criteria, it is observed that the foreground text content for the type of document that has been scanned is a relatively small percentage of the overall grey scale values, typically less than 10% in this example. Using the example values of FIGS. 9 and 10, the nominal relative histogram area percentage for each candidate IT value is as follows:
Text Area Percentage at L<94=30%
Text Area Percentage at L<32=6%

Given these computed Text Area Percentages, the candidate IT value of 94 is too high. The candidate IT value of 32, on the other hand, yields an area percentage of about 6%, which is in the desired range. A resultant IT value of 32, along with its corresponding resultant GT value, is then used for further processing. Referring to the example region R2 shown in FIGS. 7A and 7B, it appears that the IT value of 94 is associated with unwanted background content on the personal check 20. Whitened points indicated at 30 in FIG. 7B are the strong edge points found using this process and having the resultant IT and GT values.

The sequence of steps 150, 160, and 170 is performed for each region of interest in one embodiment. As a result of the processing sequence shown in FIG. 8, suitable resultant values for intensity threshold IT and gradient threshold GT for a region of interest are now available for further processing in an adaptive thresholding step 180, as shown in FIG. 1. The inputs to adaptive thresholding step 180, then, for each region of interest, are these IT and GT values, plus the high contrast object grey scale HCOGS image obtained in high contrast object grey scale image generation step 140. It is instructive to note that the Intensity Threshold IT value alone may be sufficient for documents having higher contrast, such as those having dark text foreground on a light background. Where foreground and background content are more complex, the Gradient Threshold GT value is used along with the IT value. The IT and GT threshold values generated with the steps shown in FIG. 8 can be global, that is, applied to the full scanned document, or may be local, applied only to that portion of an image in a specific region of interest.

An adaptive thresholding step 180 executes a thresholding process in order to generate a bitonal or binary image output for the document that was originally scanned in multiple color channels. This thresholding step 180 is adaptive in the sense that the IT and GT threshold values that are provided to it can control its response to image data within a specific region of interest. These threshold values can differ not only between separate documents, but also between separate regions of interest within the same document. In one embodiment, adaptive thresholding step 180 executes the processing sequence disclosed in the '659 Lee et al. patent cited earlier.

Using the processing summarized in FIG. 1 and described herein, adaptive thresholding is thus further automated, eliminating the need for operator intervention and selection of suitable IT and GT values. Furthermore, the HCOGS image provided to adaptive thresholding is optimized to produce a high quality binary output. Thus, the resulting bitonal image is superior to that obtained using current thresholding methods.

The invention has been described in detail with particular reference to certain preferred embodiments thereof, but it will be understood that variations and modifications can be effected within the scope of the invention as described above, and as noted in the appended claims, by a person of ordinary skill in the art without departing from the scope of the invention. For example, a number of different techniques could be used as alternatives to the 3×3 Sobel operator for obtaining gradient values G(L) at each pixel location. A scalar gradient sensitivity factor could be used to adjust the gradient values G(L) obtained, such as multiplying by a default value (0.8 in one embodiment). Different scalar values could be used depending on the color plane data or in order to compensate for differences in scanner sensitivity.

Scanning itself could be performed on a variety of documents and at a range of resolutions. Scan data could obtain two or more color channels, such as obtaining conventional RGB data but using only two of the color channels. A scanner obtaining more than three color channels could be used and the method extended to obtain bitonal data using color information from four or more channels.

Thus, what is provided is a method for obtaining a high quality bitonal image from a document that has a significant amount of background color content, using color scanned data.

### Parts List

20 personal check
30 edge point
40 HCOGS image
42 color image
44 binary image
100 scanning step
120 identify regions of interest step
140 high contrast object grey scale image generation step
142 computation step
144 contrast determination step
146 calculation step
147 logic condition
148 decision tree
150 edge detection step
152 gradient computation step
154 histogram maintenance step
160 measurement step
162 averaged gradient computation step
164 candidate identification step
170 validity check step
172 selection step
180 adaptive thresholding step

1. A method for obtaining bitonal image data from a document comprising:
(a) obtaining scanned color image data from at least two color channels;
(b) identifying, in the scanned color image data, at least one region of interest containing foreground content and background content;
(c) obtaining at least one threshold data value according to an image attribute that differs between the foreground content and the background content within the region of interest; and
(d) converting the scanned color image data of the document to bitonal image data according to the at least one threshold data value obtained from the region of interest.

2. The method of claim 1 wherein the foreground content comprises text.

3. The method of claim 1 wherein the color image data comprises red, green, and blue color channel data values.

4. The method of claim 1 wherein the step of obtaining at least one threshold value comprises detecting edge points in the region of interest using a Sobel operator.

5. The method of claim 1 wherein the step of converting the scanned color image data of the document to bitonal image data comprises generating a grey scale image according to image contrast in at least one of the at least two color channels.

6. The method of claim 1 wherein the step of identifying at least one region of interest on the document comprises locating reference markings on the document.

7. The method of claim 1 wherein the step of identifying at least one region of interest on the document comprises analyzing spatial variance from the scanned color image data.

8. The method of claim 1 wherein the step of identifying at least one region of interest on the document comprises entering dimensional coordinate values manually.

9. The method of claim 5 wherein converting the scanned color image data of the document to bitonal image data comprises the step of executing adaptive thresholding logic.

10. A method for obtaining a bitonal image from a document comprising:
(a) obtaining scanned color image data from at least two color channels;
(b) identifying, in the scanned color image data, at least one region of interest containing foreground content;
(c) generating a high contrast object grey scale image according to at least one attribute of the foreground content in the at least one region of interest;
(d) generating at least one threshold value for the at least one region of interest according to averaged greyscale values for edge pixels in the foreground content data; and
(e) generating the bitonal image for at least a portion of the high contrast object grey scale image according to the at least one threshold value for the at least one region of interest.

11. The method of claim 10 wherein the foreground content comprises text.

12. The method of claim 10 wherein the color image data comprises red, green, and blue color channel data values.

13. The method of claim 10 wherein the step of generating at least one threshold value comprises detecting edge points in the region of interest using a Sobel operator.

14. The method of claim 10 further comprising the step of generating a second grey scale image according to which one or more of the at least two color channels provides the highest image contrast.

15. The method of claim 10 wherein the step of identifying at least one region of interest on the document comprises locating reference markings on the document.

16. The method of claim 10 wherein the step of identifying at least one region of interest on the document comprises analyzing spatial variance.

17. The method of claim 10 wherein the at least one attribute of the foreground content used for generating a high contrast object grey scale image is contrast in at least one of the color channels.

18. The method of claim 10 wherein the step of processing at least a portion of the high contrast object grey scale image comprises the step of executing adaptive thresholding logic.

19. The method of claim 10 wherein the step of identifying at least one region of interest on the document comprises entering coordinate data values manually.

20. A method for obtaining a bitonal image from a document comprising:
(a) obtaining scanned color image data in at least two color channels;
(b) identifying foreground content in at least one region of interest on the document;
(c) generating a high contrast object grey scale image according to at least one attribute of the foreground content in the at least one region of interest;
(d) generating an intensity threshold value for the at least one region of interest according to averaged density values for edge pixels in the foreground content data;
(e) generating a gradient threshold value using a histogram of grey levels for edge pixels within the at least one region of interest; and
(f) processing the high contrast object grey scale image using the intensity and gradient threshold values to generate the bitonal image thereby.

21. The method for obtaining a bitonal image according to claim 20 wherein the step of generating a gradient threshold value comprises:
(a) forming an accumulated sum of gradient values for each grey scale value in the region of interest;
(b) counting the number of occurrences for each grey scale value within the region of interest; and
(c) computing an averaged gradient value for each grey scale value by dividing the accumulated sum of gradient values by the number of occurrences for each grey scale value.

22. A method for generating threshold values for forming a bitonal image of a document comprising:
(a) obtaining scanned color image data in at least two color channels;
(b) detecting edge pixels of foreground content of interest;
(c) computing an intensity threshold value according to the averaged intensity of the detected edge pixels; and
(d) computing a gradient threshold value according to the averaged gradient value of the detected edge pixels.

23. A method for obtaining a bitonal image from a document comprising:
(a) obtaining scanned color image data in at least two color channels;
(b) identifying foreground content in at least one region of interest on the document;
(c) obtaining grey scale and gradient values from edge pixels in the foreground content of the at least one region of interest; and
(d) converting the color image data to bitonal image data according to the grey scale and gradient values obtained from edge pixels in the foreground content.
